(19) United States
(12) Patent Application Publication
(10) Pub. No.: US 2009/0321815 A1
(43) Pub. Date: Dec. 31, 2009

(54) Non-volatile memory device and method of fabricating the same

(76) Inventors: Suk-kang Sung, Seongnam-si (KR); Jung-dal Choi, Seoul (KR); Choong-ho Lee, Yongin-si (KR); Sung-hoi Hur, Seoul (KR)

Correspondence Address: LEE & MORSE, P.C., 3141 FAIRVIEW PARK DRIVE, SUITE 500, FALLS CHURCH, VA, 22042, US

(21) Appl. No.: 12/453,035

(22) Filed: Apr. 28, 2009

(30) Foreign Application Priority Data
Jun. 30, 2008 (KR) 10-2008-0062870

(51) Int. Cl. H01L 29/792; H01L 27/092

(52) U.S. Cl. 257/324; 257/369; 257/E29.309; 257/E27.062

(57) ABSTRACT

A non-volatile memory device, including a substrate of a first conductivity type, the substrate including a plurality of wells of a second conductivity type, a plurality of memory cells in one of the plurality of wells of the second conductivity type, and a peripheral circuit including at least one first transistor of the second conductivity type on the substrate, and at least one second transistor of the first conductivity type in another one of the plurality of wells of the second conductivity type.

### BACKGROUND

1. Field

Embodiments relate to a non-volatile memory device and a method of fabricating the same, and more particularly, to a non-volatile memory device having a high program voltage and a method of fabricating the same.

2. Description of the Related Art

Semiconductor memory devices that store data are classified mainly into two categories, i.e., volatile or non-volatile memory devices. Volatile memory devices lose stored data when power cuts off, whereas non-volatile memory devices maintain the stored data even when power cuts off. A flash memory, e.g., NOR flash memory and NAND flash memory, is a type of non-volatile memory device.

Conventionally, when a program voltage of a non-volatile memory device is a high voltage, a substrate having properties of a high resistivity (high ρ (rho)) and low impurity density is used to withstand the high voltage. For example, a conventional non-volatile memory device uses a substrate having a resistivity of approximately 18 Ω cm to withstand a high-voltage between 27-30 V.

Recently, however, as a non-volatile memory device is designed to be miniaturized, a distance between memory cells of the non-volatile memory device has decreased. Accordingly, a leakage between the memory cells, i.e., word lines, may occur. Therefore, the program voltage applied to the memory cells should be reduced.

### SUMMARY

Embodiments are therefore directed to a non-volatile memory device and a method of fabricating the same, which substantially overcome one or more of the disadvantages of the related art.

It is therefore a feature of an embodiment to provide a non-volatile memory device requiring a relatively lower program voltage, thus enabling less restrictive limit of a breakdown voltage of the memory cells.

It is therefore another feature of an embodiment to provide a method of fabricating a non-volatile memory device exhibiting above feature.

At least one of the above features and other advantages may be realized by providing a non-volatile memory device, including a substrate of a first conductivity type, the substrate including a plurality of wells of a second conductivity type, a plurality of memory cells in one of the plurality of wells of the second conductivity type, and a peripheral circuit including at least one first transistor of the second conductivity type on the substrate, and at least one second transistor of the first conductivity type in another one of the plurality of wells of the second conductivity type.

The substrate may have an impurity density equal to or above a first threshold value, and the substrate may have a resistivity equal to or below a second threshold value.

The first threshold value may be 10¹⁵ cm⁻³, and the second threshold value maybe 10 Ωcm.

The plurality of memory cells may be in a well of the first conductivity type in one of the plurality of wells of the second conductivity type.

Each of the plurality of memory cells may include source/drain regions in a well of the first conductivity type, a tunneling insulation layer on a channel region between the source/drain regions, a charge storage layer on the tunneling insulation layer, a blocking insulation layer on the charge storage layer, and a gate electrode on the blocking insulation layer.

The first conductivity type may be a P-type, and the second conductivity type may be an N-type.

The first transistors may have identical structures.

The plurality of memory cells may be connected in series.

At least one of the above features and other advantages may also be realized by providing a non-volatile memory device, including a substrate of a first conductivity type, the substrate including a memory cell region and a peripheral circuit region, a first well of a second conductivity type in the memory cell region, a plurality of memory cells in the first well, a second well of the second conductivity type in the peripheral circuit region, a first transistor of the first conductivity type in the second well, and a second transistor of the second conductivity type spaced apart from the second well in the peripheral circuit region.

The substrate may have an impurity density equal to or above a first threshold value and, the substrate may have a resistivity equal to or below a second threshold value.

The first threshold value may be 10¹⁵ cm⁻³, and the second threshold value may be 10 Ωcm.

The non-volatile memory device may further include a third well of the second conductivity type formed in the peripheral circuit region, wherein another first transistor of the first conductivity type is in the third well.

The first conductivity type may be a P-type, and the second conductivity type may be an N-type.

The second transistor may be plural in number, and the structures of the plurality of second transistors may be identical to each other.

At least one of the above features and other advantages may also be realized by providing a memory system, including a non-volatile memory device, and a memory controller electrically coupled to the non-volatile memory device, wherein the non-volatile memory device includes a substrate of a first conductivity type having a plurality of wells of a second conductivity type, a plurality of memory cells formed in one of the plurality of wells, and a peripheral circuit having at least one first transistor of the second conductivity type formed on the substrate, and at least one second transistor of the first conductivity type formed in another one of the plurality of wells.

The substrate may have an impurity density equal to or above 10¹⁵ cm⁻³, and the substrate may have a resistivity equal to or below 10 Ωcm.

The first conductivity type may be an N-type, and the second conductivity type may be a P-type.

At least one of the above features and other advantages may be realized by providing a method of fabricating a non-volatile memory device, the method including forming a plurality of wells of a first conductivity type in a substrate of a second conductivity type, forming a plurality of memory cells in one of the plurality of wells, forming at least one first transistor of the second conductivity type on the substrate, and forming at least one second transistor of the first conductivity type in another one of the plurality of wells.

The method may include forming the substrate to have impurity density equal to or above a first threshold value and resistivity equal to or below a second threshold value. The first threshold value may be about 10¹⁵ cm⁻³, and the second threshold value may be about 10 Ωcm. The first conductivity type may be an N-type and the second conductivity type may be a P-type.

The method may further include forming a well of the second conductivity type as one of the plurality of wells, wherein the plurality of memory cells is formed in the well of the second conductivity type. The method may further include forming source/drain regions in the well having the second conductivity type, forming a tunneling insulation layer on a channel region between the source/drain regions, forming a charge storage layer on the tunneling insulation layer, forming a blocking insulation layer on the charge storage layer, and forming a gate electrode on the blocking insulation layer.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1 through 5 illustrate diagrams of stages in a method of fabricating a non-volatile memory device according to an embodiment;

FIG. 6 illustrates a graph showing relationship between impurity density and resistivity of a wafer;

FIG. 7 illustrates a diagram of a non-volatile memory device according to an embodiment;

FIG. 8 illustrates a flowchart of a method of fabricating a non-volatile memory device according to an embodiment;

FIG. 9 illustrates a diagram of a card according to an embodiment; and

FIG. 10 illustrates a diagram of a system according to an embodiment.

### DETAILED DESCRIPTION

Korean Patent Application No. 10-2008-0062870, filed on Jun. 30, 2008, in the Korean Intellectual Property Office, and entitled: “Non-Volatile Memory Device and Method of Fabricating the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the expression “or” is not an “exclusive or” unless it is used in conjunction with the term “either.” For example, the expression “A, B, or C” includes A alone; B alone; C alone; both A and B together; both A and C together; both B and C together; and all three of A, B, and C together, whereas the expression “either A, B, or C” means one of A alone, B alone, and C alone, and does not mean any of both A and B together; both A and C together; both B and C together; and all three of A, B, and C together.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes may be not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

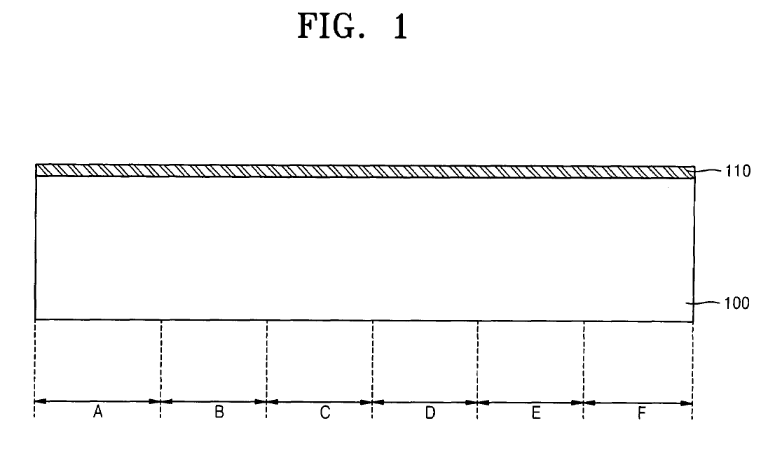

FIGS. 1 through 5 illustrate stages in a method of fabricating a non-volatile memory device according to an embodiment.

Referring to FIG. 1, an oxide layer 110 may be formed on a substrate 100 including a memory cell region A and a peripheral circuit region, including regions B to F.

The substrate 100 may be a semiconductor substrate including any one of silicon, silicon-on-insulator, silicon-on-sapphire, germanium, silicon-germanium, and gallium-arsenide. The substrate 100 may be a P-type substrate, in which a P-type impurity, e.g., Boron (B), is injected to some regions of the substrate like a low-voltage NMOS transistor region B. The substrate 100 may also be an N-type substrate, in which an N-type impurity, e.g., Arsenic (As), is injected to some regions of the substrate. Hereinafter, the substrate 100 is described as the P-type substrate for convenience, but the substrate 100 is not limited thereto, and may be the N-type substrate.

The oxide layer 110 may be a silicon oxide layer formed via, e.g., a thermal oxidation process. The oxide layer 110 formed in such way may reduce channeling. The peripheral circuit region may include a plurality of NMOS transistor regions and a plurality of PMOS transistor regions. According to the present embodiment, the plurality of NMOS transistor regions includes a low-voltage NMOS transistor region B, a high-voltage enhancement NMOS transistor region D, and a high-voltage depletion NMOS transistor region E. The plurality of PMOS transistor regions includes a low-voltage PMOS transistor region C and a high-voltage PMOS transistor region F.

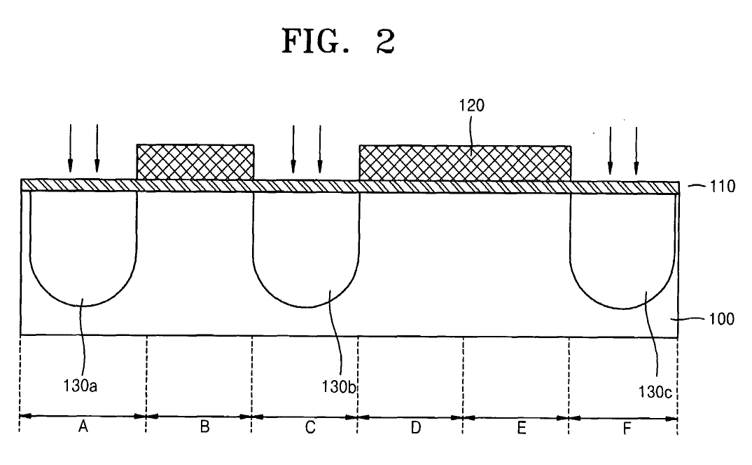

Referring to FIG. 2, a photoresist pattern 120, which exposes the memory cell region A, the low-voltage PMOS transistor region C, and the high-voltage PMOS transistor region F, may be formed on the oxide layer 110. Then, N-wells 130a, 130b, and 130c may be formed respectively in the memory cell region A, the low-voltage PMOS transistor region C, and the high-voltage PMOS transistor region F of the substrate 100. Here, the N-wells 130a, 130b, and 130c have different conductivity than that of the substrate 100. Thus, the N-wells 130a, 130b, and 130c are N-type. The N-wells 130a, 130b, and 130c may be formed by injecting micro Phosphorous (P) into the substrate 100. A PMOS transistor may be formed on the N-wells 130b and 130c. In another implementation, when the conductivity type of the substrate 100 is an N-type, the conductivity of the wells 130a, 130b, and 130c may be P-type.

According to another embodiment, a photoresist pattern (not shown), which exposes the memory cell region A and the high-voltage PMOS transistor region F, may be formed on the oxide layer 110 to form wells 130a and 130c. Here, N-type wells 130a and 130c may be formed by injecting phosphorous ions into the wells 130a and 130c by using a mask. Then, a photoresist pattern (not shown), which exposes the low-voltage PMOS transistor region C, may be formed on the oxide layer 110 to form a well 130b. Here, an N-type well 130b may be formed by injecting phosphorous ions into the well 130b by using a mask.

As such, the N-wells 130b and 130c may be formed in the low-voltage PMOS transistor region C and the high-voltage PMOS transistor region F, respectively, of the peripheral circuit region of the substrate 100. According an embodiment, however, a separate P-well may not be formed in the memory cell region A, the low-voltage NMOS transistor region B, the high-voltage enhancement NMOS transistor region D, and the high-voltage depletion NMOS transistor region E of the substrate 100. This is because the substrate 100, which is the high-impurity density P-type substrate, may be used as a body of the NMOS transistor, instead of having a separate P-well to form the NMOS transistor.

Accordingly, a process of forming a P-well is eliminated from a process of forming a non-volatile memory device, thus resulting in simplification of the process as well as the cost reduction thereof. In detail, the process of forming a photoresist pattern, exposing the low-voltage NMOS transistor region B, the high-voltage enhancement NMOS transistor region D, and the high-voltage depletion NMOS transistor region E to form a P-well, and using a mask are eliminated. Accordingly, the costs of forming a non-volatile memory device are drastically reduced.

In another embodiment, in which the conductivity type of the substrate 100 is an N-type, the substrate 100 may be used as the body of the PMOS transistor, thereby eliminating a process of forming an N-well to form a PMOS transistor.

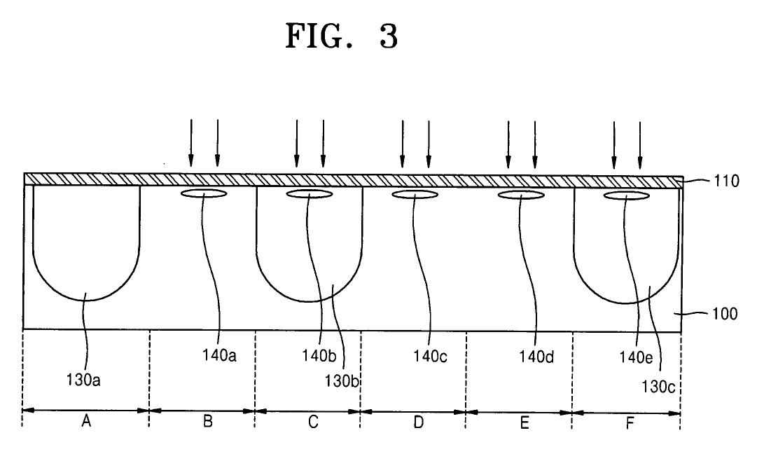

Referring to FIG. 3, a photoresist pattern (not shown) may be formed on the oxide layer 110. Impurity regions 140a, 140b, 140c, 140d, and 140e may be formed in the peripheral circuit regions B-F of the substrate 100, adjusting a threshold voltage of their respective transistors. In detail, a photoresist pattern (not shown), which exposes the low-voltage NMOS transistor region B and the low-voltage PMOS transistor region C, may be formed on the oxide layer 110. Then, the impurity regions 140a and 140b may be formed by injecting BF₂ into the low-voltage NMOS transistor region B and the low-voltage PMOS transistor region C. A photoresist pattern (not shown), which exposes the high-voltage enhancement NMOS transistor region D, may be formed on the oxide layer 110. Then, the impurity region 140c may be formed by injecting Boron (B) into the high-voltage enhancement NMOS transistor region D. A photoresist pattern (not shown), which exposes the high-voltage depletion NMOS transistor region E, may be formed on the oxide layer 110. Then the impurity region 140d may be formed by injecting arsenic (As) into the high-voltage depletion NMOS transistor region E. A photoresist pattern (not shown), which exposes the high-voltage PMOS transistor region F, may be formed on the oxide layer 110. Then the impurity region 140e may be formed by injecting phosphorous (P) into the high-voltage PMOS transistor region F.

As described above, the impurity regions 140a, 140b, 140c, 140d, and 140e may be formed by sequentially injecting impurities, e.g., BF₂, Phosphorous, Arsenic, and Boron, into the peripheral circuit region of the substrate 100. The types of the impurities, however, are not limited thereto. Also, although not illustrated in FIG. 3, an impurity region may be also formed in the memory cell region A.

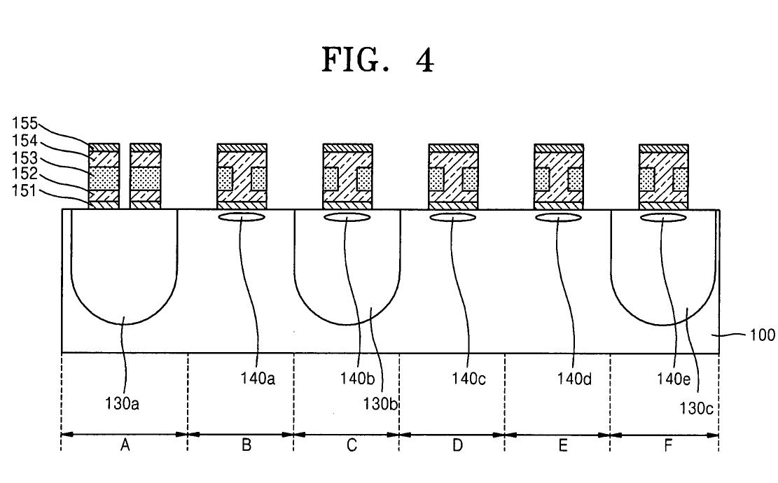

Referring to FIG. 4, gate structures, each including a plurality of stacked layers, may be formed in the memory cell region A, the low-voltage NMOS transistor region B, the low-voltage PMOS transistor region C, the high-voltage enhancement NMOS transistor region D, the high-voltage depletion NMOS transistor region E, and the high-voltage PMOS transistor region F. In the gate structure, a tunneling insulation layer 151, a charge storage layer 152, a blocking insulation layer 153, and a control gate 154 may be sequentially stacked on the substrate 100 in the stated order. Also, a hard mask layer 155 may be further stacked on the control gate 154.

In detail, the tunneling insulation layer 151 may be formed on the substrate 100. The tunneling insulation layer 151 may be formed of a silicon oxide layer, and may have a thickness of about 20 Å to about 70 Å.

Then, the charge storage layer 152 may be formed on the tunneling insulation layer 151. Here, the charge storage layer 152 may be formed of a silicon nitride layer, or a high dielectric layer having a higher dielectric constant than the silicon nitride layer. For example, the charge storage layer 152 may be formed of, e.g., a Si₃N₄ layer, a metal oxide layer, a metal nitride layer, or a combination thereof, and may have a thickness of about 40 Å to about 120 Å. Here, the charge storage layer 152 may include a trap site that stores charges passing through the tunneling insulation layer 151.

Then, the blocking insulation layer 153 may be formed on the charge storage layer 152. The blocking insulation layer 153 may block the charges trapped in the trap site of the charge storage layer 152 from escaping to the control gate 154, and may block the charges of the control gate 154 from being injected into the charge storage layer 152.

Then, the control gate 154 may be formed on the blocking insulation layer 153. The control gate 154 may be formed of at least one of TaN, TiN, W, WN, HfN, and tungsten silicide. Each gate structure may be formed by sequentially patterning the hard mask layer 155, the control gate 154, the blocking insulation layer 153, the charge storage layer 152, and the tunneling insulation layer 151.

The blocking insulation layer 153 may include a butting contact (not shown) that connects the charge storage layer 152 and the control gate 154 in the gate structures formed in the peripheral circuit region.

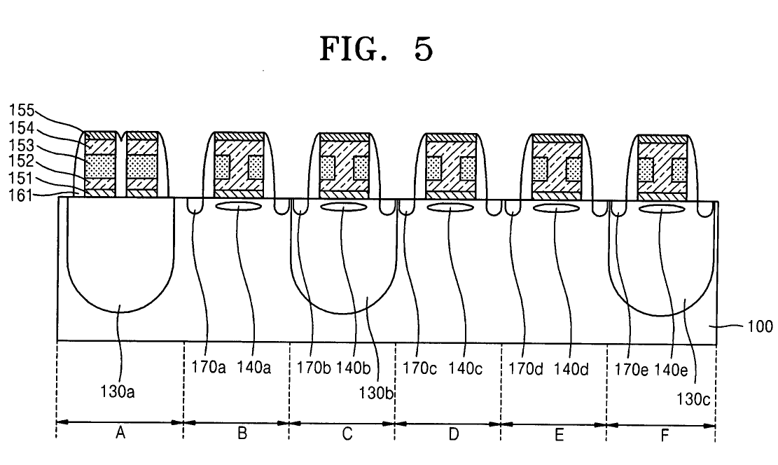

Referring to FIG. 5, source/drain regions 170a, 170b, 170c, 170d, and 170e may be formed by injecting impurities into the exposed surface of the substrate 100 on both sides of the respective gate structure, and then applying a thermal processing to the exposed surface of the substrate 100. Also, a spacer 161 may be on sidewalls of each gate structure. The spacer 161 may be in multi-layers.

In detail, the source/drain regions 170a, 170c, and 170d may be formed by injecting N+ ions into the exposed surface of the substrate 100 on both sides of the gate structure formed in the low-voltage NMOS transistor region B, the high-voltage enhancement NMOS transistor region D, and the high-voltage depletion NMOS transistor region E, respectively. Also, the source/drain regions 170b and 170e may be formed by injecting P+ ions into the exposed surface of the N-wells 130b and 130c on both sides of the gate structure formed in the low-voltage PMOS transistor region C and the high-voltage PMOS transistor region F, respectively. Although not illustrated in FIG. 5, a source/drain region may be formed by injecting predetermined ions into the exposed surface of the N-well 130a on both sides of the gate structure formed in the memory cell region A.

The method of fabricating a non-volatile memory device has been described above with reference to FIGS. 1 through 5. However, the method is not limited thereto, and may be changed according to need.

With the non-volatile memory device fabricated according to an embodiment, a program voltage applied to memory cells decreases as compared to a program voltage required by conventional technology, and thus, a limit of a breakdown voltage of the memory cells may be less restrictive. Accordingly, the resistivity of the substrate 100 does not need to be maintained high. Consequently, the non-volatile semiconductor device according to an embodiment may use the substrate 100 having a lower resistivity than that of a conventional non-volatile semiconductor device. Impurity density of the substrate 100 may increase with the decreased resistivity, as will be described in detail as follows.

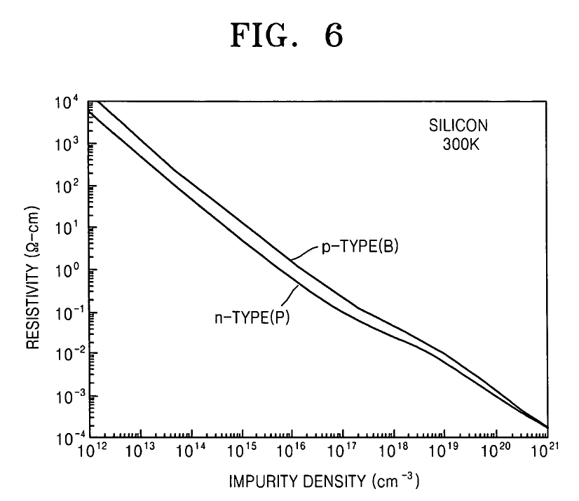

FIG. 6 illustrates a graph showing a relationship between impurity density and resistivity of a wafer.

Referring to FIG. 6, the horizontal axis denotes the impurity density of the wafer in unit of cm⁻³, and the vertical axis denotes the resistivity in unit of Ωcm. In case of a P-type substrate, a wafer including Boron (B) as impurity may be used, and in case of an N-type substrate, a wafer including Phosphorous (P) as impurity may be used.

The resistivity of a wafer used in a substrate of a conventional non-volatile memory device is approximately 18 Ωcm, and the density of Boron (B) is about 1,014 cm⁻³ in a P-type substrate. When the resistivity of the substrate 100 is decreased to about 10 Ωcm, according to an embodiment, the density of Boron may be equal to or above 10¹⁵ cm⁻³ in a P-type substrate. As such, the substrate 100 may have a lower resistivity and higher impurity density as compared to a conventional substrate.

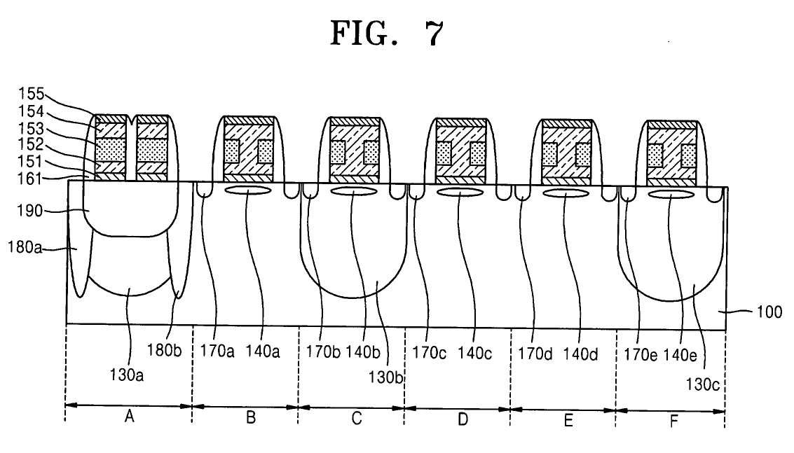

FIG. 7 is a diagram illustrating a non-volatile memory device, according to another embodiment.

Referring to FIG. 7, the non-volatile memory device may include the substrate 100 having the memory cell region A and the peripheral circuit regions B-F, a plurality of memory cells formed in the memory cell region A, and a plurality of NMOS transistors and PMOS transistors formed in the peripheral circuit regions.

The substrate 100 may be a semiconductor substrate having low resistivity and high impurity density. For example, the resistivity may be equal to or below 10 Ωcm and the impurity density may be equal to or above 10¹⁵ cm⁻³. The substrate 100 may be a P-type or an N-type according to the type of impurity. For the convenience of description, the substrate 100 of the current embodiment is a P-type substrate.

The plurality of memory cells may be formed in the deep N-well 130a of the memory cell region A. Device isolation layers 180a and 180b may be formed on each side of the deep N-well 130a, respectively. Also, a pocket P-well 190 may be formed in the deep N-well 130a, and may electrically insulate the memory cell region A and the peripheral circuit regions B-F.

Conventionally, when a P-well is formed in a peripheral circuit region, a P-well is also formed in a memory cell region. In the current embodiment, however, a separate P-well may be formed in the memory cell region A, though not formed in the peripheral circuit regions B-F of the non-volatile memory device. Accordingly, a photoresist pattern (not shown) that exposes only the memory cell region A may be formed on the substrate. The pocket P-well 190 may be formed by injecting Boron ions. Also, an impurity region (not shown) may be formed in the pocket P-well 190 by injecting BF₂ into the pocket P-well 190. In the current embodiment, the pocket P-well 190 may be formed while adjusting a threshold voltage of the memory cells.

Also, the gate structure, sequentially including the tunneling insulation layer 151, the charge storage layer 152, the blocking insulation layer 153, the control gate 154, and the hard mask layer 155 in the stated order, may be formed on the pocket P-well 190 of the memory cell region A.

The peripheral circuit region may include the low-voltage NMOS transistor region B, the low-voltage PMOS transistor region C, the high-voltage enhancement NMOS transistor region D, the high-voltage depletion NMOS transistor region E, and the high-voltage PMOS transistor region F. The N-wells 130b and 130c may be formed in the low-voltage PMOS transistor region C and the high-voltage PMOS transistor region F, respectively, to form the PMOS transistors. A separate P-well, however, is not formed in the low-voltage NMOS transistor region B, the high-voltage enhancement NMOS transistor region D, and the high-voltage depletion NMOS transistor region E. Instead, the substrate 100 having a high impurity density may be used as the body of the PMOS transistors.

The impurity regions 140a, 140b, 140c, 140d, and 140e may be formed in the peripheral circuit regions B-F, respectively, to adjust a threshold voltage of their respective transistor. The source/drain regions 170a, 170c, and 170d may be formed by injecting N+ ions into the low-voltage NMOS transistor region B, the high-voltage enhancement NMOS transistor region D, and the high-voltage depletion NMOS transistor region E, respectively. The source/drain regions 170b and 170e may be formed by injecting P+ ions into the low-voltage PMOS transistor region C and the high-voltage PMOS transistor region F, respectively.

The gate structures may be formed in the peripheral circuit regions B-F and the spacer 161 may be formed on both sidewalls of each gate structure. Also, an inter-layer insulation layer (not shown) may be formed between the gate structures. In FIG. 7, the non-volatile memory device includes only two gate structures for the convenience of description, but the number of gate structures is not limited thereto.

Also, as described above, when the conductivity type of the substrate 100 is an N-type, according to another embodiment, a process of forming an N-well to form a PMOS transistor is omitted, and, instead, the substrate 100 may be used as the body of the PMOS transistor.

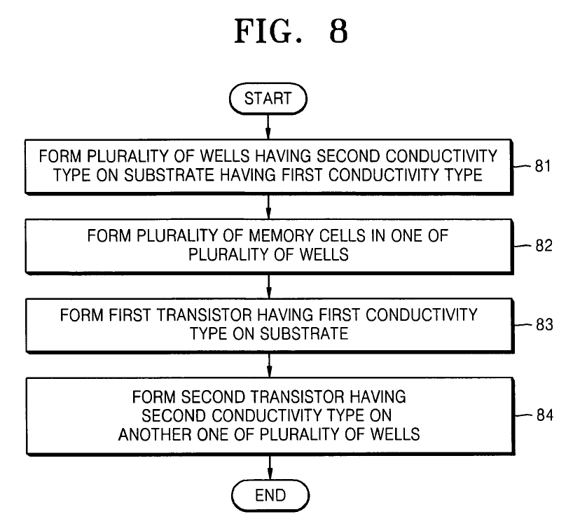

FIG. 8 illustrates a flowchart of a method of fabricating a non-volatile memory device according to an embodiment.

Referring to FIG. 8, in operation 81, a plurality of wells having a second conductivity type may be formed on a substrate having a first conductivity type. Here, the substrate may have a impurity density equal to or above a first threshold value and a resistivity equal to or below a second threshold value, where the first threshold value may be about 10¹⁵ cm⁻³, and the second threshold value may be about 10 Ωcm.

In operation 82, a plurality of memory cells may be formed in one of the plurality of wells.

In operation 83, at least one first transistor having the first conductivity type may be formed on the substrate.

In operation 84, at least one second transistor having the second conductivity type may be formed on another well of the plurality of wells. The order of performing operations 83 and 84 may be switched, or operations 83 and 84 may be performed simultaneously.

According to another embodiment, forming a well having the first conductivity type in one of the plurality of wells may be further included in the method. Here, the plurality of memory cells may be formed in the well having the first conductivity type.

According to another embodiment, the method may further include forming source/drain regions in the well having the first conductivity type, forming a tunneling insulation layer in a channel region between the source/drain regions, forming a charge storage layer on the tunneling insulation layer, forming a blocking insulation layer on the charge storage layer, and forming a gate electrode on the blocking insulation layer.

Here, the first conductivity type is a P-type and the second conductivity type is an N-type.

According to an embodiment, the non-volatile memory device may be a NAND flash memory. Since a program voltage of a conventional NAND flash memory is higher than that of other non-volatile memories, a substrate having low impurity density is conventionally used. According to an embodiment, however, a substrate having high impurity density may be used in the NAND flash memory, and the substrate may be also used as a body of a transistor having a conductivity type different from that of the substrate. As such, the method is the most efficient when is used to fabricate a NAND flash memory, but the method may be also used in fabricating other non-volatile memory devices having a high program voltage.

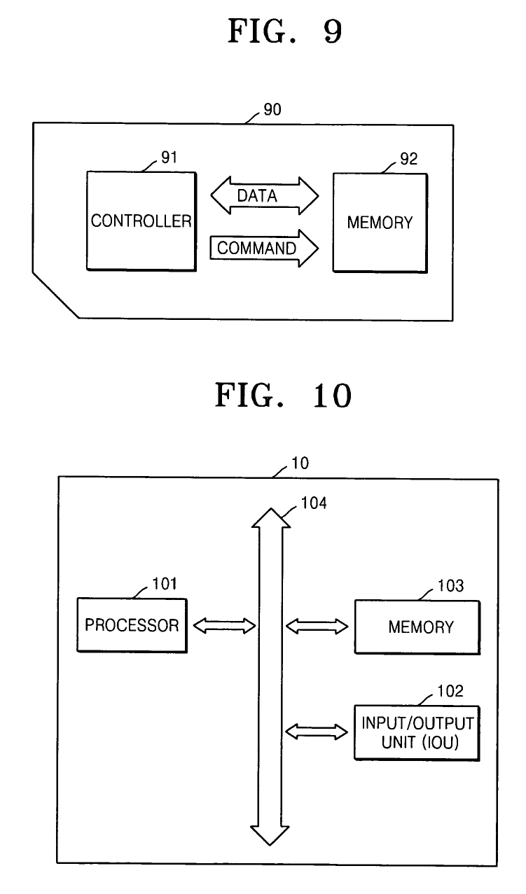

FIG. 9 illustrates a diagram of a memory system, e.g., a card 90, according to an embodiment.

Referring to FIG. 9, the card 90 may be disposed in such a way that a controller 91 and a memory 92 can exchange an electric signal. For example, when a command is transmitted from the controller 91, the memory 92 transmits data back to the controller 91. The memory 92 may include the non-volatile memory device of FIG. 7. Examples of the card 90 include a memory stick card, a SmartMedia card, a secure digital (SD) card, a mini secure digital card (mini SD), and a MultiMediaCard (MMC).

FIG. 10 illustrates a diagram of memory system 10 according to another embodiment.

Referring to FIG. 10, a processor 101, an input/output unit (IOU) 102 and a memory 103 included in the system 10 communicate with each other via a bus 104. A controller (not shown) may command the memory 103 when data is to be received from or transmitted to the bus 104. The processor 101 executes a program and controls the system 10. In an implementation, the processor 101 may serve as the controller. The IOU 102 is used to input or output data to and from the system 10. The system 10 exchanges data with an external device (not shown), such as a personal computer or a network, via the IOU 102. The memory 103 may include the non-volatile memory device of FIG. 7, e.g., the memory 103 may store codes and/or data to operate the processor 101. The system 10 may be used in, e.g., a mobile phone, an MP3 player, a navigation device, a portable multimedia player (PMP), a solid state disk (SSD), or household appliances.

Embodiments may also be embodied as computer readable codes on a computer readable recording medium, e.g., a tangible medium. The computer readable recording medium may be any data storage device that can store programs or data and thereafter be able to read by a computer system. The computer readable recording medium may be read-only memories (ROMs), random-access memories (RAMs), CD-ROMs, DVDs, magnetic tapes, hard disks, floppy disks, flash memory, optical data storage devices. In another implementation, carrier waves (such as data transmission through the Internet) may provide the computer readable codes. A program stored in a recording medium may be expressed in a series of instructions used directly or indirectly within a device with a data processing capability, i.e., computers. Thus, a term “computer” involves all devices with data processing capability, in which a particular function is performed according to a program using a memory, input/output devices, and arithmetic logics.

By forming a non-volatile semiconductor device using the substrate that has lower resistivity and high impurity density, a reduction in a program voltage applied to a memory cell may be achieved. Further, as a process of forming a well of the first conductivity type to form the first transistor is eliminated, the process of forming the non-volatile memory device may be simplified and cost of forming thereof may be reduced.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A non-volatile memory device, comprising:
a substrate of a first conductivity type, the substrate including a plurality of wells of a second conductivity type;
a plurality of memory cells in one of the plurality of wells of the second conductivity type; and
a peripheral circuit including:
at least one first transistor of the second conductivity type on the substrate, and
at least one second transistor of the first conductivity type in another one of the plurality of wells of the second conductivity type.

2. The non-volatile memory device as claimed in claim 1, wherein:
the substrate has an impurity density equal to or above a first threshold value, and
the substrate has a resistivity equal to or below a second threshold value.

3. The non-volatile memory device as claimed in claim 2, wherein:
the first threshold value is 10¹⁵ cm⁻³, and
the second threshold value is 10 Ωcm.

4. The non-volatile memory device as claimed in claim 1, wherein the plurality of memory cells are in a well of the first conductivity type in one of the plurality of wells of the second conductivity type.

5. The non-volatile memory device as claimed in claim 4, wherein each of the plurality of memory cells includes:
source/drain regions in a well of the first conductivity type;
a tunneling insulation layer on a channel region between the source/drain regions;
a charge storage layer on the tunneling insulation layer;
a blocking insulation layer on the charge storage layer; and
a gate electrode on the blocking insulation layer.

6. The non-volatile memory device as claimed in claim 1, wherein:
the first conductivity type is a P-type, and
the second conductivity type is an N-type.

7. The non-volatile memory device as claimed in claim 1, wherein the first transistors have identical structures.

8. The non-volatile memory device as claimed in claim 1, wherein the plurality of memory cells are connected in series.

9. A non-volatile memory device, comprising:
a substrate of a first conductivity type, the substrate including a memory cell region and a peripheral circuit region;
a first well of a second conductivity type in the memory cell region;
a plurality of memory cells in the first well;
a second well of the second conductivity type in the peripheral circuit region;
a first transistor of the first conductivity type in the second well; and
a second transistor of the second conductivity type spaced apart from the second well in the peripheral circuit region.

10. The non-volatile memory device as claimed in claim 9, wherein:
the substrate has an impurity density equal to or above a first threshold value and,
the substrate has a resistivity equal to or below a second threshold value.

11. The non-volatile memory device as claimed in claim 10, wherein:
the first threshold value is 10¹⁵ cm⁻³, and
the second threshold value is 10 Ωcm.

12. The non-volatile memory device as claimed in claim 9, further comprising a third well of the first conductivity type formed in the first well, wherein the plurality of memory cells are formed in the third well.

13. The non-volatile memory device as claimed in claim 9, wherein:
the first conductivity type is a P-type, and
the second conductivity type is an N-type.

14. The non-volatile memory device as claimed in claim 9, wherein the second transistor is plural in number, and the structures of the plurality of second transistors are identical to each other.

15. A memory system, comprising:
a non-volatile memory device; and
a memory controller electrically coupled to the non-volatile memory device, wherein the non-volatile memory device includes:
a substrate of a first conductivity type having a plurality of wells of a second conductivity type;
a plurality of memory cells formed in one of the plurality of wells; and
a peripheral circuit having at least one first transistor of the second conductivity type formed on the substrate, and at least one second transistor of the first conductivity type formed in another one of the plurality of wells.

16. The system as claimed in claim 15, wherein:
the substrate has an impurity density equal to or above 10¹⁵ cm⁻³, and
the substrate has a resistivity equal to or below 10 Ωcm.

17. The system as claimed in claim 15, wherein:
the first conductivity type is an N-type, and
the second conductivity type is a P-type.
